(19) United States
(12) Patent Application Publication
(10) Pub. No.: US 2008/0245397 A1
(43) Pub. Date: Oct. 9, 2008

(54) System and Method of Manufacturing Thermoelectric Devices

(75) Inventors: Joshua E. Moczygemba, Wylie, TX (US); James L. Bierschenk, Rowlett, TX (US)

Correspondence Address: BAKER BOTTS L.L.P., 2001 ROSS AVENUE, SUITE 600, DALLAS, TX, 75201-2980, US

(73) Assignee: Marlow Industries, Inc., Dallas, TX (US)

(21) Appl. No.: 11/696,581

(22) Filed: Apr. 4, 2007

(51) Int. Cl. H01L 37/00; H01L 21/44; H01L 35/30; H01L 35/34

(52) U.S. Cl. 136/201; 136/205; 438/666

(57) ABSTRACT

A method of forming an P/N-type array of P-type and N-type material includes stacking a plurality of P-type material wafers and a plurality of N-type material wafers into a P/N-type array. At least one spacer is provided between adjacent wafers. The P-type material wafers and the N-type material wafers are boned together the into a composite P/N-type brick. The method may also include providing a second composite P/N-type brick. A plurality of channels and fingers are created in the first and second composite P/N-type bricks. The first and second composite P/N-type bricks are fit together to form a P/N-type mosaic. Alternatively, the method may include providing a single P/N-type brick. A plurality of channels is created in the composite P/N-type brick. The channels are then back filled with an electrically and thermally insulating adhesive so that a P/N-type grid of P-type elements and N-type elements is formed.

### TECHNICAL FIELD OF THE INVENTION

The present invention relates to thermoelectric devices and more particularly, to a system and method of manufacturing thermoelectric devices.

### BACKGROUND OF THE INVENTION

The basic theory and operation of thermoelectric devices has been developed for many years. Presently available thermoelectric devices used for cooling typically include an array of thermocouples which operate in accordance with the Peltier effect. Thermoelectric devices may also be used for heating, power generation and temperature sensing.

Thermoelectric devices may be described as essentially small heat pumps which follow the laws of thermodynamics in the same manner as mechanical heat pumps, refrigerators, or any other apparatus used to transfer heat energy. A principal difference is that thermoelectric devices function with solid state electrical components (thermoelectric elements or thermocouples) as compared to more traditional mechanical/fluid heating and cooling components. The efficiency of a thermoelectric device is generally limited to its associated Carnot cycle efficiency reduced by a factor which is dependent upon the thermoelectric figure of merit (ZT) of the materials used in fabrication of the associated thermoelectric elements. Materials used to fabricate other components such as electrical connections, hot plates and cold plates may also affect the overall efficiency of the resulting thermoelectric device.

Thermoelectric materials such as alloys of Bi₂Te₃, PbTe and BiSb were developed thirty to forty years ago. More recently, semiconductor alloys such as SiGe have been used in the fabrication of thermoelectric devices. Commercially available thermoelectric materials are generally limited to use in a temperature range between 200K and 1300K with a maximum ZT value of approximately one. Typically, a thermoelectric device incorporates both P-type and N-type semiconductor alloys as the thermoelectric materials.

In accordance with one method for the manufacture of a thermoelectric device, a billet of P-type material may be extruded to form a P-type ingot. Similarly, a billet of N-type material may be extruded to form an N-type billet. In particular embodiments, P-type and N-type billets may be plastically deformed or hotpressed. The P and N-type ingots are sliced into wafers, the wafers are diced into elements, and the elements are mechanically loaded into a grid or “matrix” with the desired pattern and assembled upon a plate. P-type and N-type elements are typically arranged into rectangular arrays, in order to form a thermoelectric device. P-type and N-type legs alternate in both array directions. A metallization may be applied to the P-type wafers, N-type wafers, and/or the plate, in order to arrange the P-type wafers and the N-type wafers electrically in series and thermally in parallel.

For many thermoelectric devices, the elements dimensions are approximately 0.6 mm by 1.0 mm. Generally, the legs have a square cross-section perpendicular to the direction of current flow. Commonly, there are 18 to 36 pairs of P-type and N-type elements. Due to the size of the P-type and N-type elements, the elements are typically separated by hand, by using bowl sorters with pick and place automation, by using mass loading vibratory techniques, or any combination of the three, for installation upon the plate according to a predetermined generally alternating pattern. This method is time-consuming and intricate, and requires specialized equipment and experienced operators.

### SUMMARY OF THE INVENTION

In accordance with teachings of the present invention, the design and preparation of semiconductor materials for fabrication of thermoelectric devices is provided to enhance manufacturing and operating efficiencies.

In accordance with a particular embodiment of the present invention, a method of forming an array of P-type material and N-type material includes providing P-type material wafers and N-type material wafers. The P-type material wafers and N-type material wafers may be alternately stacked into an array, each wafer being separated from the next by a spacer. The wafers are then bonded to form a composite P/N-type brick using, for example, an electrically and thermally insulating adhesive applied to streets of space that are created between the wafers.

In accordance with another embodiment of the present invention, a method of forming an array of P-type material and N-type material includes providing a first and second composite P/N-type brick. A number of channels and fingers are created in the first and second composite P/N-type bricks such that the fingers and channels of each may interlock. The first and second composite P/N-type bricks are joined together such that the fingers and channels of each interlock to form a mosaic of P-type elements and N-type elements. An electrically and thermally insulating adhesive is then applied between the interlocking fingers of the first and second composite P/N-type bricks. The first and second composite P/N-type bricks are thereby bonded to form a P/N-type array.

In accordance with another embodiment of the present invention, a method of forming an array of P-type material and N-type material includes providing a single composite P/N-type brick. A number of channels are created in the composite P/N-type brick. The channels are then back-filled with an electrically and thermally insulating adhesive such that a grid of P-type elements and N-type elements is formed.

Technical advantages of particular embodiments of the present invention include a method for forming a P/N-type array having a predetermined number of P-type elements and a predetermined number of N-type elements, arranged according to a predetermined configuration. Therefore, a P/N-type array may be formed to suit the particular application and desired end product, simplifying the assembly of a thermoelectric device.

### BRIEF DESCRIPTION OF THE DRAWINGS

FIG. 1 illustrates a flowchart of steps for creating an array of P-type material and N-type material according to one embodiment.

FIG. 1A illustrates ingots and wafers of P-type and N-type material.

FIG. 1B illustrates a P/N-type array.

FIG. 1C illustrates another P/N-type array.

FIG. 1D illustrates excess portions of P-type material and N-type material being removed from a P-N-type array.

FIG. 2 illustrates a flowchart of steps for creating an array of P-type material and N-type material according to another embodiment.

FIG. 2A illustrates a pair of composite P/N-type bricks.

FIG. 2B illustrates a pair of composite P/N-type bricks in which a number of fingers and channels have been created.

FIG. 2C illustrates an enlarged view of the fingers and channels created in each of the composite P/N-type bricks of FIG. 2B.

FIG. 2D illustrates the joining process of the two composite P/N-type bricks of FIG. 2B.

FIG. 2E illustrates a P/N-type array of P-type elements and N-type elements arranged in a checkerboard pattern.

FIG. 2F illustrates excess material being removed from a P/N-type array.

FIG. 3 illustrates a flowchart of steps for creating an array of P-type material and N-type material according to another embodiment.

FIG. 3A illustrates a composite P/N-type brick.

FIG. 3B illustrates a series of channels created in the composite P/N-type brick displayed in FIG. 3A.

FIG. 3C illustrates an electrically and thermally insulating adhesive being applied to the series of channels in the composite P/N-type brick displayed in FIG. 3C.

FIG. 3D illustrates a P/N-type grid of P-type elements and N-type elements arranged in rows.

FIG. 3E illustrates excess material being removed from a P/N-type grid.

FIG. 3F illustrates a current-carrying metallization.

FIG. 4A illustrates a schematic drawing showing an isometric view of a thermoelectric device having multiple thermoelectric elements which may be fabricated from semiconductor materials incorporating teachings of the present invention.

FIG. 4B illustrates an electrical schematic drawing of one thermocouple of the thermoelectric device of FIG. 4A.

### DETAILED DESCRIPTION OF THE INVENTION

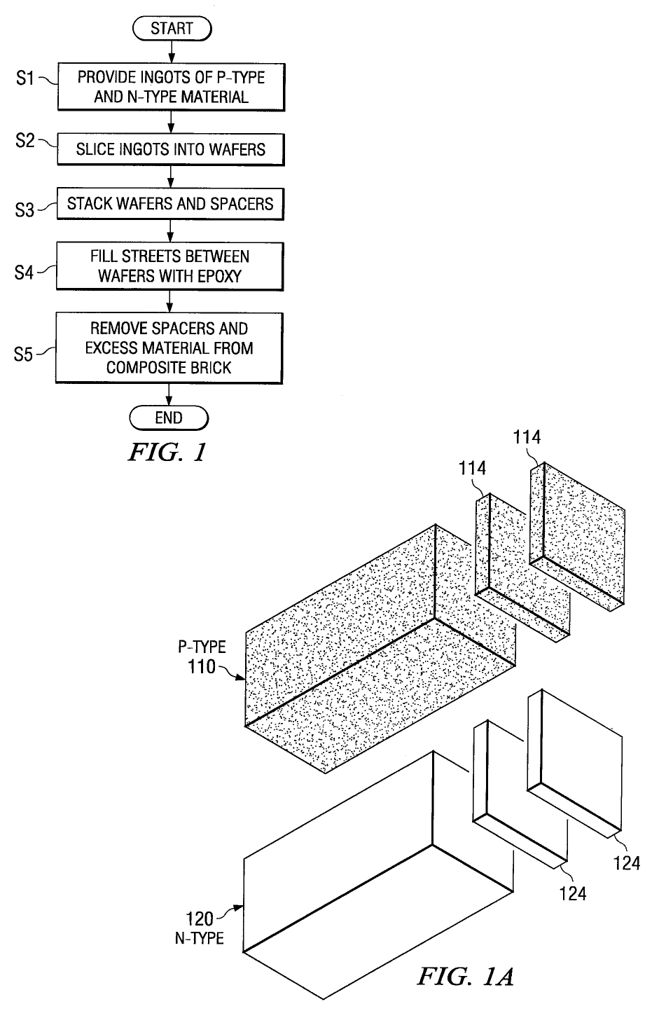

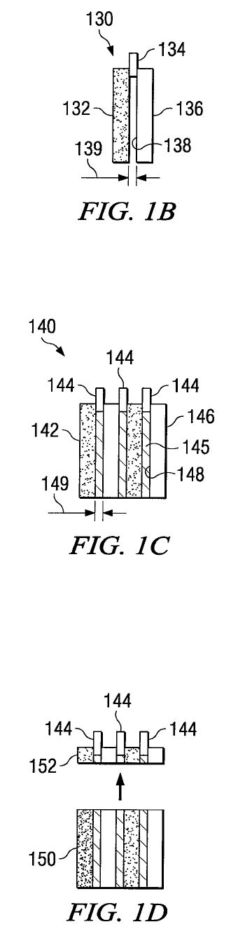

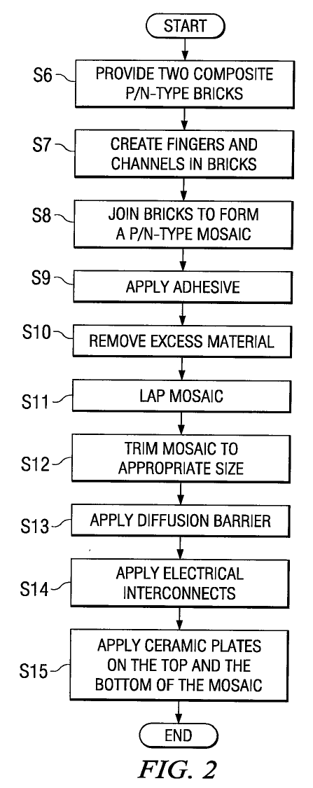

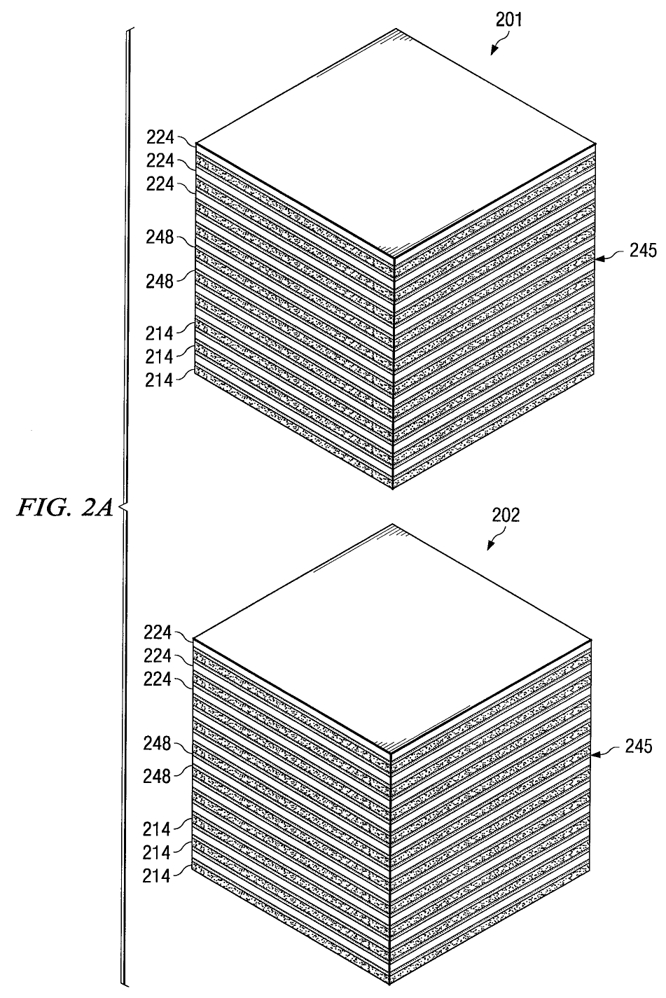

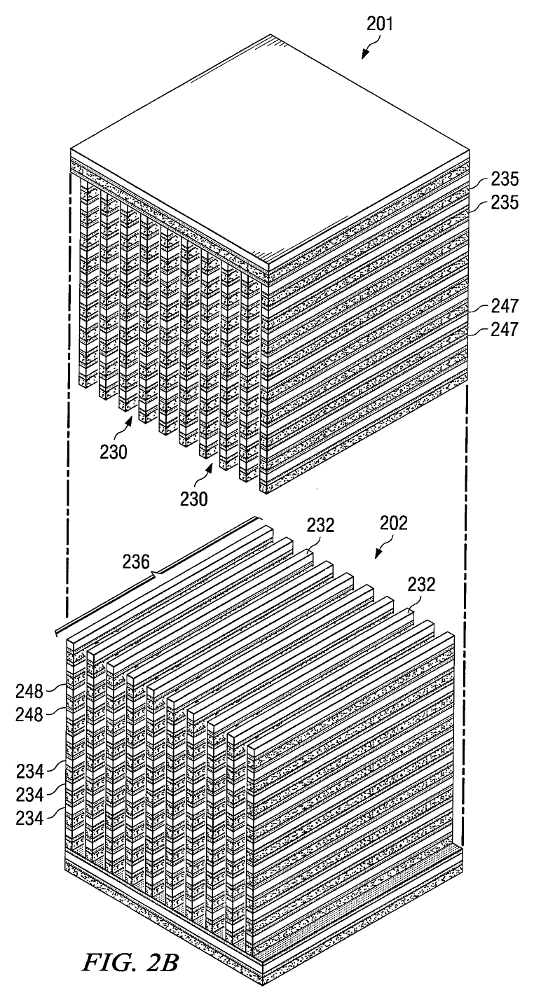

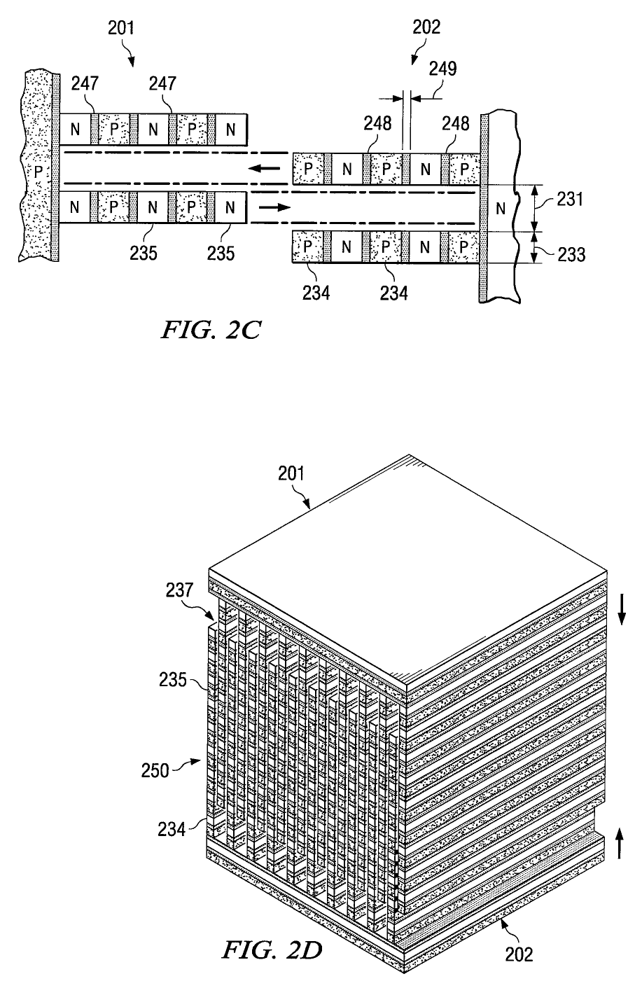

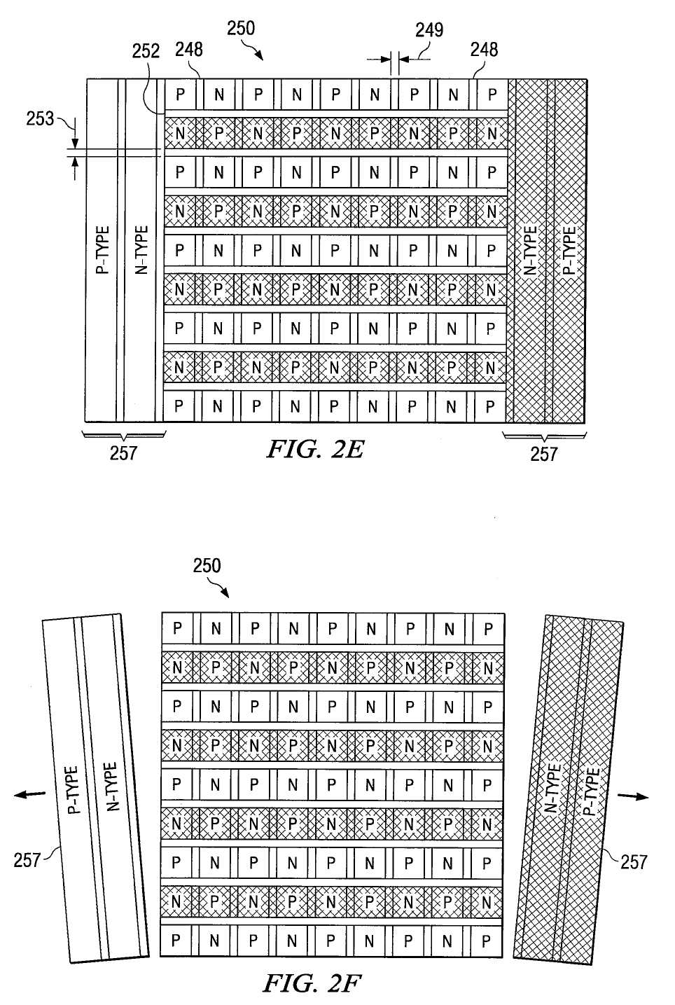

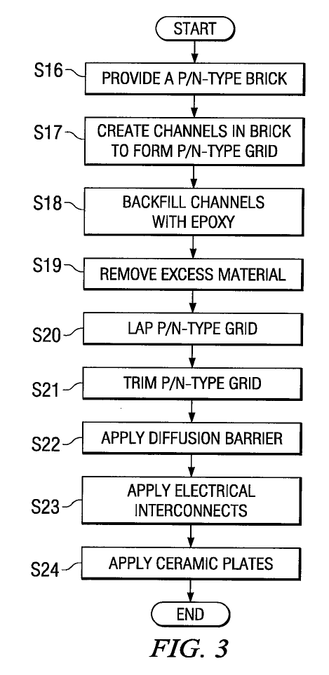

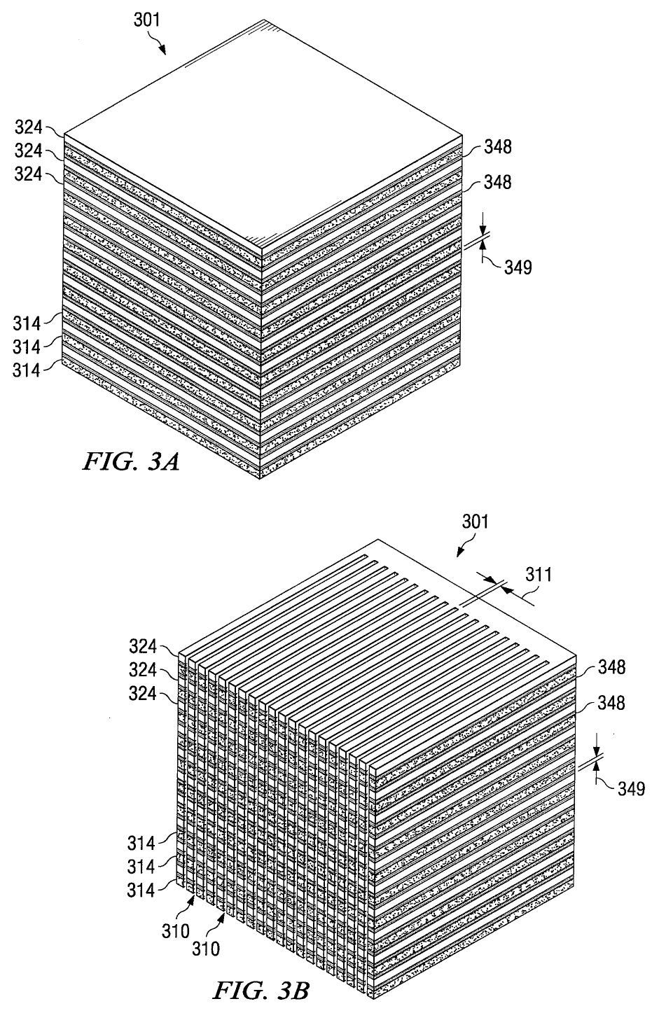

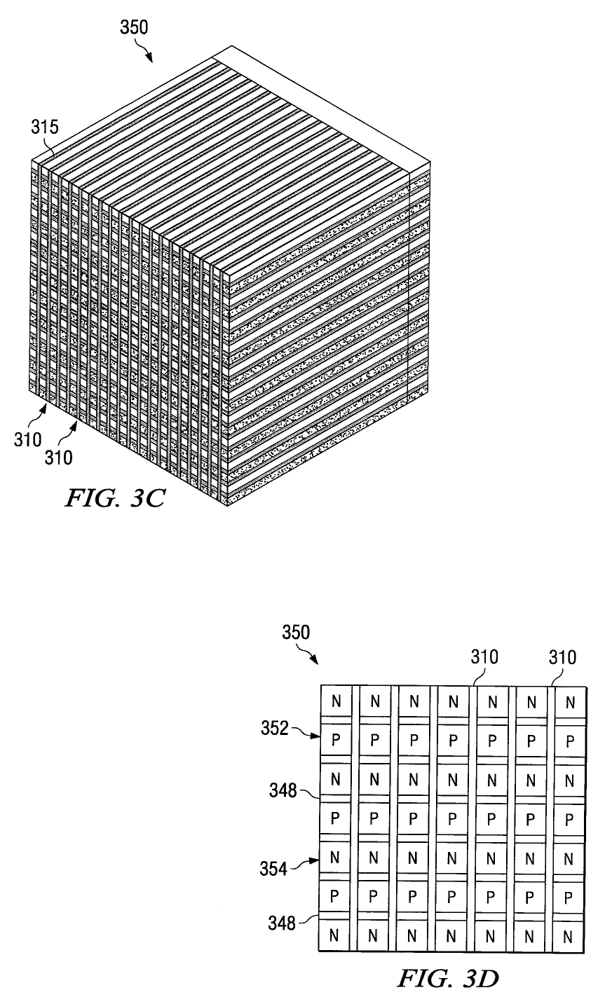

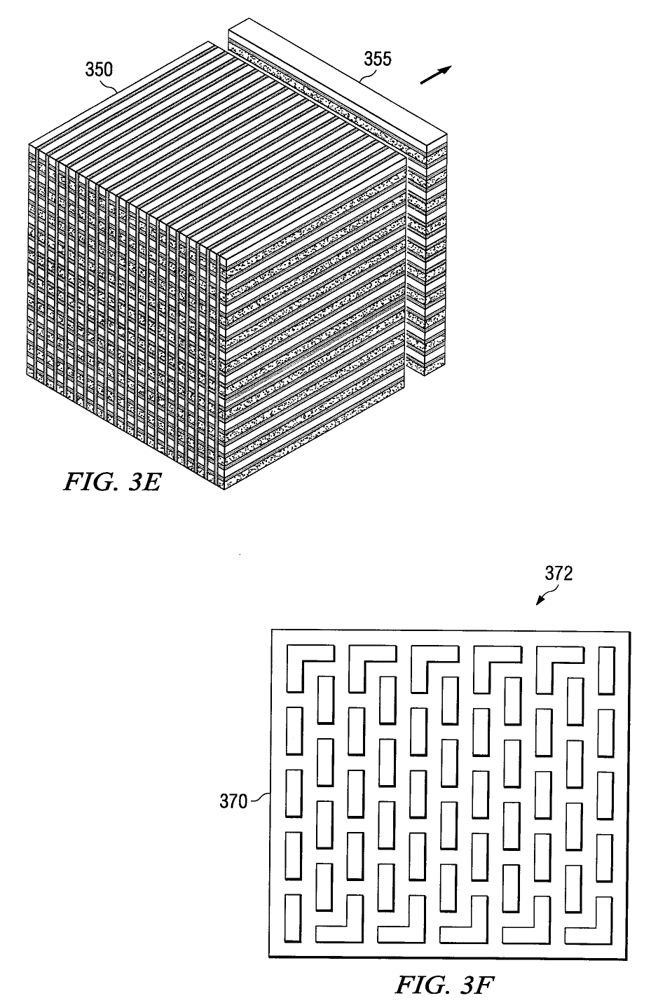

FIGS. 1, 2, and 3 each display flowcharts respectively depicting embodiments of the present invention for manufacturing thermoelectric devices. More specifically, FIG. 1 displays certain steps in an embodiment of the present invention for creating a composite P/N-type brick that may be used in many ways, including either of the processes for manufacturing thermoelectric devices illustrated in FIGS. 2 and 3.

Referring to FIG. 1, a process for manufacturing the composite P/N-type brick begins at S1 where an ingot of P-type material and an ingot of N-type material are provided. In step S2, the ingot of P-type material and the ingot N-type material are sliced into P-type material wafers and N-type material wafers, respectively. In step S3, the P-type material wafers and the N-type material wafers are stacked into a P/N-type array with each adjacent wafer being separated by a spacer. Each spacer contacts only a fraction of the surface area of the two wafers that it separates and thereby creates a street of space between the two wafers. In step S4, the streets between the P-type material wafers and the N-type material wafers are filled with an electrically and thermally insulating adhesive. In step S5, the spacers and any unbonded P-type material and N-type material are removed, leaving a composite P/N-type brick.

FIG. 1A illustrates the components of steps S1 and S2 in more detail. Specifically pictured is an ingot of P-type material 110 and an ingot N-type material 120 which have been partially separated into a plurality of individual P-type material wafers 114 and N-type material wafers 124. The P-type material wafers 114 and N-type material wafers 124 may be separated from their respective ingots in various ways (e.g., diamond blade slicing, wire saw slicing, wire edm, RAM edm, laser cutting, etc.).

The ingot of P-type material 110 and the ingot of N-type material 120 may be created, for example, out of a fine grained Bismuth-telluride based material such as a Bi2 Te3 based Micro-Alloyed Material (MAM) as produced by Marlow Industries with an optimized Z at room temperature. An advantage of MAM material is that it has a dimensionally fine grain structure and an absence of cleavage planes. These characteristics aid in creating tall and narrow P-type and N-type elements—a process which will be described in further detail below with respect to FIGS. 2 and 3. In particular embodiments, the ingot of P-type material 110 and the ingot of N-type material 120 may be created out of lead telluride or skutterudites. Traditional materials such as Bridgman Bi2 Te3 material have weak cleavage planes and may make tall and narrow P-type and N-type element geometries more difficult to form.

The ingot of P-type material 110 and the ingot N-type material 120 are not meant to be limited to any particular configuration or size nor are the P-type material wafers 114 and/or N-type material wafers 124 meant to be limited to any shape or thickness. However, in an embodiment, the P-type material wafers 114 and/or N-type material wafers 124 are generally rectangular and may have a thickness 115 of 300 to 400 microns, may have a height 116 of between 10-15 millimeters and a width 117 of 10-15 millimeters. Such geometries will partially determine the geometries of the P-type elements and N-type elements that may be created using the processes described with respect to FIGS. 2 and 3 discussed below. In alternative embodiments, the ingots and/or resulting wafers may include round, oval, square, or other shaped cross-sections, within the teachings of the present invention.

FIG. 1B illustrates the components of step S3 in more detail. In step S3 a number of wafers are stacked into an array, each adjacent wafer being separated by a spacer. Specifically pictured is a P/N-type array 130 containing a P-type material wafer 132, an N-type material wafer 136, and a spacer 134. In the pictured embodiment of the present invention, spacer 134 is placed along the outside edge of the P-type material wafer 132 and N-type material wafer 136 such that spacer 134 only comes in contact with a fraction (e.g., less than 10%) of the surface area of the adjacent face of each adjacent wafer. Such positioning of the spacer creates a street 138 of space (having a street-width 139) between the P-type material wafer 132 and N-type material wafer 136 contained in array 130. Similar arrays of P/N-type material may be constructed in various sizes and configurations by altering the number and sequence of the P-type material wafers, N-type material wafers, and spacers contained in the array.

Spacer 134 is not meant to be limited to any particular size or configuration, but may be chosen to conform to a predetermined criteria (e.g., to achieve a predetermined, uniform street-width). In particular embodiments, spacer 134 may range in thickness from 10 microns to 250 microns. As an example and not by way of limitation, if spacer 134 were to have a thickness of 75 microns, the street 138 separating P-type material wafer 132 and N-type material wafer 136 would have a street-width 139 of approximately 75 microns. Furthermore, spacer 134 may be placed in any number of positions relative to the adjacent P-type material wafer 132 and N-type material wafer 136; however, spacer 134 may be placed along the outside edge of P-type material wafer 132 and N-type material wafer 136 as pictured so as to provide for easy removal of the spacer in a later stage of the process described in FIG. 1D. In embodiments where a plurality of spacers, P-type wafers, and N-type wafers are included a P/N-type array, the spacers may be uniformly positioned along the outside edges of the wafers throughout the array. Such positioning may provide for easy removal of the spacers in a later stage of the process described in FIG. 1D.

FIG. 1C illustrates the components of step S4 in more detail. In step S4, the streets in the array are filled with an electrically and thermally insulating adhesive. Specifically pictured is another P/N-type array 140 containing a plurality of P-type material wafers 142, N-type material wafers 146, and spacers 144. Consistent with the spacers 144 are a plurality of streets 148 running between each of the P-type material wafers 142 and N-type material wafers 146 contained in the array 140. Once the construction of the P/N-type array 140 has been completed, each of the streets 148 are filled with an electrically and thermally insulating adhesive 145 (e.g., epoxy). The P/N-type array 140 may further be constructed having streets of sufficient width so that capillary action wicks the electrically and thermally insulating adhesive 145 into the streets 148.

The number of P-type material wafers 142 and N-type material wafers 146 contained in array 140 is not limited in any particular fashion; however, in certain embodiments the sum total of P-type material wafers and N-type material wafers contained in an array may be limited to approximately thirty. Said number of wafers yields approximately 500-600 P-type elements (FIG. 2C) and 500-600 N-type elements (FIG. 2C) using the processes described in FIG. 2 discussed below.

The electrically and thermally insulating adhesive 145 is not limited to any particular compound; however, it may be an epoxy with a dielectric strength of approximately 550 volts/mil, and a thermal conductivity of approximately 0.82 W/mC. In particular embodiments, the electrically and thermally insulating adhesive 145 may be Stycast W19, Stycast 1266, Loctite Hysol FP453 1, or other epoxy. Other electrically and thermally insulating adhesives and application techniques are available for use within the teachings of the present invention. For example, an electrically and thermally insulating adhesive having a relatively low thermal conductivity may be appropriate to apply between the P-type material wafers and N-type material wafers. The electrically and thermally insulating adhesive may be one or more of various chemically inert electrical insulators/thermal insulators. An advantage of using epoxy for the thermally insulating adhesive 145 is that the epoxy hardens into place and supports the P-type material wafers and N-type material wafers during any sculpturing processes such as diamond blade sawing or wire sawing. Furthermore, the use of epoxy may provide for a robust and durable end product.

The street-width 149 of each one of the streets 148 running between the P-type material wafers 142 and N-type material wafers 146 is not limited to any particular dimension; however, in certain embodiments, the street-width 149 of each one of the streets 148 may be chosen to satisfy a predetermined criteria. For example, the efficiency of thermoelectric devices is partially determined by the amount of parasitic thermal loss caused by the insulating material separating the P-type and N-type material. Accordingly, it may be desirable to minimize the amount of insulating material separating the P-type material from the N-type material. In the present embodiment, the electrically and thermally insulating adhesive 145 plays the role of the insulating material. Therefore, since, in the current embodiment, the amount of electrically and thermally insulating adhesive 145 to be applied between the P-type material wafers 142 and N-type material wafers 146 is dictated by the street-width 149 of each of the streets 148, the street-width 149 may be chosen so as to minimize the amount of electrically and thermally insulating adhesive 145. Furthermore, the street-width 149 of each one of the streets 148 may be uniform. One way of achieving uniform street-width is by choosing the spacers 144 such that they are all of uniform thickness.

FIG. 1D displays step S5 in more detail. Once the streets 148 have been filled with the electrically and thermally insulating adhesive 145, any unbonded P-type and N-type material 152 and the spacers 144 may be removed, leaving a composite P/N-type brick 150. In the present embodiment, the excess P-type and N-type material 152 and the spacers 144 may be removed after the electrically and thermally insulating adhesive 148 has cured, and furthermore, may be removed in various ways (e.g., diamond blade slicing, wire saw slicing, wire edm, RAM edm, laser cutting, etc.).

FIG. 2 displays a flowchart of steps in an embodiment of the present invention wherein two composite P/N-type bricks are sculpted to fit together such that a P/N-type mosaic of P-type elements and N-type elements is formed. According to the present embodiment, the process for forming a P/N-type mosaic begins with step S6 wherein a first composite P/N-type brick and a second composite P/N-type brick are provided. In step S7 a number of channels and fingers are created in both of the composite P/N-type bricks. The channels may extend transversely through the P-type material wafers and the N-type material wafers contained in each P/N-type brick. In step S8, the first composite P/N-type brick is joined with the second composite P/N-type brick such that the fingers in the first composite P/N-type brick interlock with the channels in the second composite P/N-type brick and vice versa. Furthermore, in step S8 the fingers of the first composite P/N-type brick are aligned with the fingers in the second composite P/N-type brick to form a P/N-type mosaic of P-type elements and N-type elements that are distributed in a checkerboard pattern. In step S9 an electrically and thermally insulating adhesive is applied between the fingers of the first composite P/N-type brick and the second composite P/N-type brick so that the P/N-type mosaic becomes permanently bonded together. In step 10 any excess material is removed from the P/N-type mosaic. In step S11 the P/N-type mosaic may be lapped so that the P-type elements and N-type elements contained in the P/N-type mosaic have the desired element-length. In step S12 the P/N-type mosaic is trimmed so that it contains a desired number of P-type elements and N-type elements. In step S13 a diffusion barrier is applied to the P/N-type mosaic. In step S14 electrical interconnects are applied to the P/N-type mosaic. In step S15 ceramic plates are applied to the P/N-type mosaic.

FIG. 2A illustrates the components of step S6 in more detail. In step S6, a first composite P/N-type brick 201 is provided, and a second composite P/N-type brick 202, is provided. Composite brick 201 and composite brick 202 can be formed using any number of methods including the method outlined in FIG. 1. Both composite P/N-type bricks contain a plurality of P-type wafers 214 (similar to the P-type wafers 114 in FIG. 1A), N-type wafers 224 (similar to the N-type wafers 124 in FIG. 1A), and streets 248 (similar to the streets 148 in FIG. 1C) that have been filled with an electrically and thermally insulating adhesive 245 (similar to the electrically and thermally insulating adhesive 145 in FIG. 1C). Composite brick 201 and composite brick 202 are not meant to be limited to any particular size, configuration, or composition; however, in the present embodiment both composite bricks are chosen to be approximately equal in size, configuration, and composition.

FIG. 2B illustrates the components of step S7 in more detail. Specifically in step S7, a number of channels 230 are created in composite brick 201 and composite brick 202 such that the channels 230 extend transversely through the P-type material wafers 214 and the N-type material wafers 224 contained in each of the composite bricks. As a consequence of creating the channels 230 in each of the composite bricks, a number of fingers 232 are also created in each of the composite bricks. Each of the fingers 232 contains a plurality of P-type elements 234 and N-type elements 235, each element having an element-length 236 and each element being separated by a street 247 of adhesive having a street-width 249 (see FIG. 2C).

The channels 230 may be created using a number of different mechanisms (e.g., diamond blade slicing, wire saw slicing, wire edm, RAM edm, laser cutting, etc.); however in certain embodiments the channels 230 are created using a wire saw because wire sawing may be a low stress method of cutting. In the present embodiment, all of the channels 230 in the first composite P/N-type brick 201 are sized such that they will accept the fingers 232 created in the second P/N-type brick 202 and vice versa.

The P-type elements 234 and the N-type elements 235 are not limited to any particular size; however, in certain embodiments extremely long or extremely short aspect ratios are desirable. An aspect ratio is the numerical ratio of the length to cross-sectional area of a thermoelectric element. In one embodiment, an element may have a length of 10-15 millimeters and a cross section of 300-400 microns.

FIG. 2C illustrates an enlarged view of a section of composite brick 201 and 202 after the channels 230 and fingers 232 have been created. Each one of the channels 230 has an associated channel-width 231 and each one of the fingers 232 has an associated finger-width 233. Each of the fingers 232 contain a plurality of P-type elements 234 and N-type elements 235, each element being separated by a street 247 of adhesive having a street-width 249.

In the pictured embodiment, the respective channel-widths 231 of every one of the channels 230 are approximately equal to one another, the respective finger-widths 233 of every one of the fingers 232 are approximately equal to one another, and the respective street-widths 249 of every one of the streets 248 are approximately equal to one another. Furthermore, in the present embodiment, the channel-width 231 is equal to a single finger-width 233 plus two street-widths 249. In mathematical terms, one equation for determining channel-width could be:

channel-width=1*finger-width+2*street-width

where finger-width and street-width are independent variables that can be chosen to conform to a predetermined criteria. Such sizing of the channels 230 provides an advantage of creating uniform spacing between all of the P-type elements 234 and N-type elements 235 once the first composite P/N-type brick 201 and second composite P/N-type brick 202 have been joined together (see FIG. 2E). One of ordinary skill in the art will understand that alternative equations and/or other spacing criteria may be used in particular embodiments to configure the spacing between the P-type elements 234 and N-type elements 235 to suit any number predetermined criteria (e.g., unequal spacing).

As discussed with respect to FIG. 2B above, in embodiments where the channels 230 are created using a saw, the kerf of the cut may be equal to a single finger-width 233 plus two street-widths 249 in order to create uniform spacing between all of the P-type elements 234 and N-type elements 235 once the first composite P/N-type brick 201 and second composite P/N-type brick 202 have been joined together.

Finger-width 233 is not required to be any particular dimension; however, in certain embodiments, finger-width 233 may be chosen to satisfy a predetermined criteria (e.g., to achieve a desired aspect ratio). Similarly, street-width 249 is not required to be any particular dimension; however, in certain embodiments, street-width 249 may be chosen to satisfy a predetermined criteria (e.g., to minimize the amount of insulating material separating P-type elements from the N-type elements). In certain embodiments, street-width 249 may be chosen to be 75 microns. Such sizing would provide 75 microns of clearance between each of the fingers in the first composite P/N-type brick 201 and second composite P/N-type brick 202 during the joining process.

FIG. 2D illustrates step S8 in more detail. In step S8, the first composite P/N-type brick 201 is joined with the second composite P/N-type brick 202 such that the channels 230 created in the first element 201 interlock with the fingers 232 created in the second composite brick 202 and vice versa. This method of joining is commonly referred to as a finger joint 237 and may be achieved using any number of fingers and channels of varying sizes. Once joined, the interlocking section of composite brick 201 and composite brick 202 form a P/N-type mosaic 250 having a checkerboard pattern of P-type elements 234 and N-type elements 235.

The P/N-type mosaic 250 may contain any number of P-type elements 234 and N-type elements 235; however, in an embodiment where the sum total of P-type material wafers and N-type material wafers contained in each composite P/N-type brick is limited to approximately thirty, the above described process may yield between 500-600 P-type elements and 500-600 N-type elements, each with an elemental cross section of 300-400 microns. Such a result may be achieved by using a street-width of 75 microns.

FIG. 2E illustrates an enlarged view of the P/N-type mosaic 250 that is created by the joining of composite brick 201 and composite brick 202. Notice that due to the sizing of the channel-width 231 according to the method described with respect to FIG. 2C, there is an approximately uniform line of space 252 having a line-width 253 running between each of the joined fingers 232. Furthermore, line-width 253 is approximately equal to the street-width 249 of the streets 248 of adhesive running between each of the P-type elements 234 and N-type elements 235. Notice that the fingers of both composite bricks have been aligned such that the streets 248 of adhesive running between the P-type elements and N-type elements line up with one another to maintain approximately straight streets 248 of adhesive throughout the P/N-type mosaic 250. One of ordinary skill in the art will understand that in particular embodiments, parameters such as channel-width 311 and street-width 349 may be varied to suit any number of predetermined criteria (e.g., unequal spacing between the P-type elements and N-type elements).

In step S9, each line of space 252 is filled with an electrically and thermally insulating adhesive 255 (similar to the electrically and thermally insulating adhesive 45 in FIG. 1C) such the P/N-type mosaic 250 permanently bonds together. Thus, each one of the P-type elements 234 and N-type elements 235 contained in P/N-type mosaic 250 may be separated from every other adjacent P-type or N-type element by an approximately uniform street of electrically and thermally insulating adhesive.

FIG. 2F illustrates the trimming process in more detail. In step S10, any excess material 257 is trimmed away from the P/N-type mosaic 250.

The amount of excess material 257 may vary according to the relative depth of the channels 230 created in the first composite P/N-type brick 201 and the second composite P/N-type brick 202. Specifically, the amount of excess material on each P/N-type brick may be approximately equal to the percentage of the P/N-type brick containing the P-type material wafers and N-type material wafers through which the channels do not transversely pass. Shallow channels may result in more excess material, while deep channels may result in less excess material. In an embodiment, the material 257 may be removed after the electrically and thermally insulating adhesive cured, and furthermore may be removed in various ways (e.g., diamond blade slicing, wire saw slicing, wire edm, RAM edm, laser cutting, etc.).

In step S11 the P/N-type mosaic 250 may be shaped using one or more processes such as lapping, cutting, grinding, or polishing so that the P-type elements and N-type elements contained in P/N-type mosaic 250 have a desired element-length 236 (FIG. 2B), and further, in step S12 the P/N-type mosaic may be trimmed so that it contains a desired number of P-type elements and N-type elements.

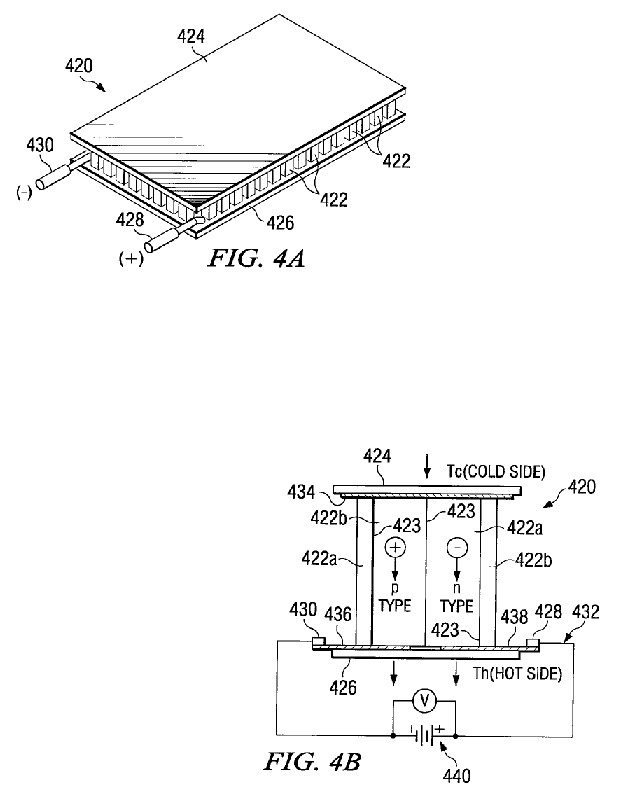

In particular embodiments, the element length of the thermoelectric elements present in a thermoelectric array may be constant across the thermoelectric array. In other words, the element length of each thermoelectric element may be substantially the same as the element length of every other thermoelectric element. Such a configuration would allow a top ceramic plate 424 (FIG. 4A) to be approximately parallel to a bottom ceramic plate 426 (FIG. 4A) while contacting each thermoelectric element.

At step S13 a diffusion barrier metallization may be applied to at least a subset of the P-type elements and N-type elements. The diffusion barrier may comprise nickel or any other suitable barrier material (e.g., molybdenum). The diffusion barrier may optionally be provided in order to provide a surface for soldering and inhibit interactions between the solder and the thermoelectric materials. In a particular embodiment of the present invention, nickel may be applied as the diffusion barrier, using a combination of photolithography and/or shadow masking and plating operations. Multiple layers may also be used for the diffusion barrier. The layers may be applied during the same step, and may comprise different materials.

Next, at step S14, a patterned, current-carrying metallization may optionally be provided on one or both sides of the P/N-type mosaic to form a thermoelectric circuit thereupon. For example, at least one series circuit could be fabricated on the P/N-type mosaic.

In step S15, ceramic plates may be applied to both sides of the P/N-type mosaic. The ceramic plates may provide electrical isolation of the thermoelectric circuit from another component of the thermoelectric assembly. In a particular embodiment, each plate may include a patterned metallization, to provide a solder based thermal link and/or enhance current carrying characteristics of the thermoelectric circuit.

FIG. 3, displays a flowchart of steps in an embodiment of the present invention wherein a plurality of channels are created in a single P/N-type brick which are then back-filled with an electrically and thermally insulating adhesive such that a P/N-type grid containing a plurality of P-type elements and N-type elements is formed. According to the present embodiment, the process for forming the P/N-type grid begins with step S16 wherein a composite P/N-type brick is provided. In step S17 a number of channels are created in the composite P/N-type brick such that the channels extend transversely through the P-type wafers and N-type wafers contained in the P/N-type brick. In step S18 the channels are back-filled with an electrically and thermally insulating adhesive. In step S19 any excess material is removed from the P/N-type grid. In step S20 the P/N-type grid may be lapped so that the P-type elements and N-type elements contained in the P/N-type grid have the desired element-length. In step S21 the P/N-type grid may be trimmed so that it contains a desired number of P-type elements and N-type elements. In step S22 a diffusion barrier is applied to the P/N-type grid. In step S23 electrical interconnects are applied to the P/N-type grid. In step S24 ceramic plates are applied to the P/N-type grid.

FIG. 3A illustrates a composite P/N-type brick 301 with characteristics similar to composite P/N-type brick 101 (FIG. 2A). Composite brick 301 contains a plurality of P-type material wafers 314 (similar to P-type material wafers 114 in FIG. 1A), N-type material wafers 324 (similar to N-type material wafers 124 in FIG. 1A), and streets 348 filled with an electrically and thermally insulating adhesive 315 (similar the electrically and thermally insulating adhesive 145 in FIG. 1C), each having an associated street-width 349.

The street-width 349 of each one of the streets 348 running between the P-type material wafers 314 and N-type material wafers 324 is not limited to any particular dimension; however, in certain embodiments, the street-width 349 of each one of the streets 348 may be chosen to satisfy a predetermined criteria. For example, the efficiency of thermoelectric devices is partially determined by the amount of parasitic thermal loss caused by the insulating material separating the P-type and N-type type material. Accordingly, it may be desirable to minimize the amount of insulating material separating the P-type material from the N-type material. In the present embodiment, the electrically and thermally insulating adhesive 315 plays the role of the insulating material. Therefore, since, in the current embodiment, the amount of electrically and thermally insulating adhesive 315 to be applied between the P-type material wafers 314 and N-type material wafers 324 is dictated by the street-width 349 of each of the streets 348, the street-width 349 may be chosen so as to minimize the amount of electrically and thermally insulating adhesive 315. Furthermore, the street-width 349 of each one of the streets 348 may be uniform.

FIG. 3B illustrates the components of step S17 in more detail. Specifically, in step S17, a number of channels 310 (each having an associate identical channel-width 311) are created in the composite brick 301. Once the channels 310 have been created in composite brick 301 a grid of P-type elements and N-type elements will be formed. The grid of P-type elements and N-type elements will be discussed in further detail with respect to FIG. 3D.

In the pictured embodiment, the respective channel-widths 311 of every one of the channels 310 are approximately equal to one another and the respective street-widths 349 of every one of the streets 348 are approximately equal to one another. Furthermore, the channel-width 311 of every one of the channels 310 may be approximately equal to the street-width 349 of one of the streets 348 running between the wafers of P-type material 314 and the wafers of N-type material 324 contained in the P/N-type composite brick 301. One of ordinary skill in the art will understand that in particular embodiments, parameters such as channel-width 311 and street-width 349 may be varied to configure the spacing between the P-type elements 352 and N-type elements 354 to suit any number of predetermined criteria (e.g., unequal spacing).

The channels 310 may extend transversely through the wafers of P-type material and N-type material that are contained in composite brick 301. The channels 310 may be created using a number of different mechanisms (e.g., diamond blade slicing, wire saw slicing, wire edm, RAM edm, laser cutting, etc.); however in certain embodiments, the channels 310 are created using a wire saw because wire sawing may be a low stress method of cutting. Furthermore, in embodiments where the channels 310 are created using a saw, the kerf of the cut may be equal to a single street-width 349 in order to create uniform spacing between all of the P-type elements (FIG. 3D) and N-type elements (FIG. 3D).

FIG. 3C shows step S18 in more detail. Specifically, in step S18 the channels 310 are back-filled with electrically and thermally insulating adhesive 315.

The electrically and thermally insulating adhesive 315 is not limited to any particular compound; however, it may be an epoxy with a dielectric strength of 550 volts/mil, and a thermal conductivity of 0.82 W/mC. In particular embodiments, the electrically and thermally insulating adhesive 145 may be Stycast W19, Stycast 1266, Loctite Hysol FP4531, or other epoxy. Other electrically and thermally insulating adhesives and application techniques are available for use within the teachings of the present invention. For example, an electrically and thermally insulating adhesive having a relatively low thermal conductivity may be appropriate to apply between the P-type material and N-type material. The electrically and thermally insulating adhesive may be one or more of various chemically inert electrical insulators/thermal insulators. An advantage of using epoxy for the thermally insulating adhesive 315 is that the epoxy hardens into place and supports the P-type material and N-type material during any sculpturing processes such as diamond blade sawing or wire sawing. Furthermore, the use of epoxy my provide for a robust and durable end product.

FIG. 3D illustrates an enlarged view of composite brick 301 after the channels 310 have been created and filled with adhesive. Notice that the channels 310 and the streets 348 form a P/N-type grid 350 having a plurality of P-type elements 352 and N-type elements 354. Notice that in the pictured embodiment, the P-type elements 352 and N-type elements 354 may be arranged in rows rather than in a checkerboard pattern.

FIG. 3E shows the components of step S19 in more detail. Specifically in step S9, any excess material 355 is removed from the P/N-type grid 350, and furthermore in steps S20 and S21, P/N-type grid 350 may be lapped and trimmed so that it contains a desired number of P-type elements 352 and N-type elements 354 each having a desired element length.

The amount of excess material 355 may vary according to the relative depth of the channels 310 created in the composite P/N-type brick 301. Specifically, the amount of excess material on the composite P/N-type brick 301 may be approximately equal to the percentage of the composite P/N-type brick 301 containing the P-type material wafers and N-type material wafers through which the channels 310 do not transversely pass. Shallow channels may result in more excess material, while deep channels may result in less excess material. In an embodiment, the material 355 may be removed after the electrically and thermally insulating adhesive cured, and furthermore, may be removed in various ways (e.g., diamond blade slicing, wire saw slicing, wire edm, RAM edm, laser cutting, etc.).

In particular embodiments, the element length of the thermoelectric elements present in a thermoelectric array may be constant across the thermoelectric array. In other words, the element length of each thermoelectric element may be substantially the same as the element length of every other thermoelectric element. Such a configuration may allow a top ceramic plate 424 (FIG. 4A) to be approximately parallel to a bottom ceramic plate 426 (FIG. 4A) while contacting each thermoelectric element.

At step S22 one or more diffusion barrier metallizations may be applied to at least a subset of the P-type elements and N-type elements. The diffusion barrier may comprise nickel or any other suitable barrier material (e.g., molybdenum). The diffusion barrier may optionally be provided in order to provide a surface for soldering and inhibit interactions between the solder and the thermoelectric materials. In a particular embodiment of the present invention, nickel may be applied as the diffusion barrier, using photolithography or shadow masking and plating operations. Multiple layers may also be used for the diffusion barrier. The layers may be applied during the same step, and may comprise different materials.

Next, at step S23, one or more patterned, current-carrying metallizations may optionally be provided on one or both sides of the P/N-type grid to form a thermoelectric circuit thereupon. For example, at least one series circuit could be fabricated on the P/N-type grid.

FIG. 3F illustrates an example current-carrying metallization 370. In embodiments of the present invention where the P/N-type grid 350 contains rows of P-type elements 352 and N-type elements 354, the circuit couples between each element may require an L-shaped wrap-around 372 at the end of each row of elements.

In step S24, ceramic plates may be applied to both sides of the P/N-type grid. The ceramic plates may provide electrical isolation of the thermoelectric circuit from another component of the thermoelectric assembly. In a particular embodiment, each plate may include a patterned metallization, to provide a solder-based thermal link and/or enhance current carrying characteristics of the thermoelectric circuit.

FIG. 4A illustrates a thermoelectric device 420 including a plurality of thermoelectric elements (sometimes referred to as “thermocouples”) 422 disposed between a cold plate 424 and a hot plate 426. Electrical connections 428 and 430 are provided to allow thermoelectric device 420 to be electrically coupled with an appropriate source of DC electrical power. In a particular embodiment of the present invention, thermoelectric elements 422 may be formed from a single component having both P-type and N-type regions (for example, the P/N-type mosaic described with respect to FIG. 2F, or the P/N-type grid described with respect to FIG. 3D). Therefore, manufacturing, handling, and assembly of thermoelectric device 420 may be simplified, and performance of the thermoelectric device 420 may be enhanced.

Thermoelectric device 420 may be used as a heater, cooler, electrical power generator and/or temperature sensor. If thermoelectric device 420 were designed to function as an electrical power generator, electrical connections 428 and 430 would represent the output terminals from such a power generator operating between hot and cold temperature sources.

FIG. 4B is a schematic representation of an electrical circuit 432 of single stage thermoelectric device 420. Electrical circuit 432 may also be incorporated into thermoelectric elements or thermocouples to convert heat energy into electrical energy. Electric circuit 432 generally includes two or more thermoelectric elements 422 fabricated from dissimilar semiconductor materials such as N-type thermoelectric elements 422a and P-type thermoelectric elements 422b. Thermoelectric elements 422 are typically configured in a generally alternating N-type element to P-type element arrangement. A barrier 423 (for example, an electrically and thermally insulating epoxy) may be formed between each P-type element 422a and adjacent N-type elements 422b. In many thermoelectric devices, semiconductor materials with dissimilar characteristics are connected electrically in series and thermally in parallel. The phrase “semiconductor materials” is used in this application to include semiconductor compounds, semiconductor alloys and mixtures of semiconductor compounds and alloys formed in accordance with teachings of the present invention for use in fabricating thermoelectric elements and thermoelectric devices.

N-type semiconductor materials generally have more electrons than necessary to complete the associated crystal lattice structure. P-type semiconductor materials generally have fewer electrons than necessary to complete the associated crystal lattice structure. The “missing electrons” are sometimes referred to as “holes.” The extra electrons and extra holes are sometimes referred to as “carriers.” The extra electrons in N-type semiconductor materials and the extra holes in P-type semiconductor materials are the agents or carriers which transport or move heat energy between cold side or cold plate 424 and hot side or hot plate 426 through thermoelectric elements 422 when subject to a DC voltage potential. These same agents or carriers may generate electrical power when an appropriate temperature difference is present between cold side 424 and hot side 426.

Conductors 434, 436 and 438 may be metallization formed on thermoelectric elements 422a, 422b and/or on the interior surfaces of plates 424 and 426.

Ceramic materials are frequently used to manufacture plates 424 and 426 which define in part the cold side and hot side, respectively, of thermoelectric device 420. Commercially available thermoelectric devices that function as a cooler generally include two ceramic plates with separate P-type and N-type thermoelectric elements formed from bismuth telluride (Bi₂,Te₃) alloys disposed between the ceramic plates and electrically connected with each other.

When DC electrical power from power supply 440 is properly applied to thermoelectric device 420 heat energy will be absorbed on cold side 424 of thermoelectric elements 422 and will be dissipated on hot side 426 of thermoelectric device 420. A heat sink or heat exchanger (sometimes referred to as a “hot sink”) may be attached to hot plate 426 of thermoelectric device 420 to aid in dissipating heat transferred by the associated carriers and phonons through thermoelectric elements 422 to the adjacent environment. In a similar manner, a heat sink or heat exchanger (sometimes referred to as a “cold sink”) may be attached to cold side 424 of thermoelectric device 420 to aid in removing heat from the adjacent environment. Thus, thermoelectric device 420 may sometimes function as a thermoelectric cooler when properly connected with power supply 440. However, since thermoelectric devices are a type of heat pump, thermoelectric device 420 may also function as a heater, power generator, or temperature sensor.

Although the present invention has been described in several embodiments, a myriad of changes and modifications may be suggested to one skilled in the art, and it is intended that the present invention encompass such changes and modifications as fall within the scope of the present appended claims.

What is claimed is:

1. A method of forming an array of P-type and N-type material, comprising:
stacking a plurality of P-type material wafers and a plurality of N-type material wafers into a P/N-type array;
providing at least one spacer between adjacent wafers; and
bonding together the P-type material wafers and the N-type material wafers into a composite P/N-type brick.

2. The method of claim 1, wherein stacking a plurality of P-type material wafers and a plurality of N-type material wafers into a P/N-type array comprises stacking the P-type material wafers and the N-type material wafers in an alternating relationship.

3. The method of claim 1, further comprising positioning the at least one spacer between the P-type material wafers and the N-type material wafers such that streets of a predetermined width are created between the P-type material wafers and the N-type material wafers.

4. The method of claim 1, further comprising positioning the at least one spacer so that it comes in contact with only a fraction of the surface area of the adjacent face of any adjacent wafer.

5. The method of claim 1, wherein the at least one spacer is selected such that it comes in contact with only a fraction of the surface area of the adjacent face of any adjacent wafer.

6. The method of claim 1, further comprising removing the at least one spacer between adjacent P-type material wafers and N-type material wafers after the P-type material wafers and the N-type material wafers have been bonded together.

7. The method of claim 1, further comprising removing at least a portion of any unbonded P-type material and N-type material after the P-type material wafers and the N-type material wafers have been bonded together.

8. The method of claim 1, wherein providing at least one spacer between adjacent wafers comprises providing the at least one spacer between each immediately adjacent wafer in the P/N-type array.

9. The method of claim 1, wherein a plurality of the spacers are of uniform, predetermined thickness.

10. The method of claim 1, wherein bonding together the P-type material wafers and the N-type material wafers into a composite P/N-type brick comprises applying an electrically and thermally insulating adhesive between the P-type material wafers and the N-type material wafers.

11. The method of claim 10, wherein the electrically and thermally insulating adhesive is epoxy.

12. The method of claim 10, wherein the spacers comprise a predetermined thickness that allows capillary action to wick the electrically and thermally insulating adhesive between the P-type material wafers and the N-type material wafers.

13. The method of claim 1 wherein the composite P/N-type brick comprises a first composite P/N-type brick, and further comprising:
providing a second composite P/N-type brick;
creating a plurality of channels and fingers in the first composite P/N-type brick;
creating a plurality of channels and fingers in the second composite P/N-type brick;
fitting together the first composite P/N-type brick and second composite P/N-type brick;
bonding together the first composite P/N-type brick and second composite P/N-type brick into a P/N-type mosaic.

14. The method of claim 13 wherein:
streets of approximately uniform width are present between the P-type material wafers and the N-type material wafers in each of the first and second composite P/N-type bricks;
the respective widths of each channel are approximately equal to one another;
the respective widths of each finger are approximately equal to one another; and
the width of each channel corresponds to the desired width of an individual finger plus the width of two of the streets of approximately uniform width.

15. The method of claim 13, wherein creating a plurality of channels and fingers in the first composite P/N-type brick and second composite P/N-type brick comprises sawing the channels in the composite P/N-type bricks such that the channels extend transversely through the P-type material wafers and the N-type material wafers.

16. The method of claim 15, wherein:
streets of approximately uniform width are present between the P-type material wafers and the N-type material wafers in each of the composite P/N-type bricks;
the respective widths of each channel are approximately equal to one another;
the respective widths of each finger are approximately equal to one another; and
the kerf of the cut left from sawing is approximately equal in width to the desired width of an individual finger plus the width of two of the streets of approximately uniform width.

17. The method of claim 13, wherein fitting together the first composite P/N-type brick and second composite P/N-type brick comprises interlocking the plurality of channels and fingers created in the first composite P/N-type brick with the plurality of channels and fingers created in the second composite P/N-type brick.

18. The method of claim 13, wherein the first composite P/N-type brick and second composite P/N-type brick are fit together using a finger joint.

19. The method of claim 13, wherein bonding together the first composite P/N-type brick and second composite P/N-type brick comprises applying an electrically and thermally insulating adhesive between the first composite P/N-type brick and second composite P/N-type brick.

20. The method of claim 19, wherein the electrically and thermally insulating adhesive is epoxy.

21. The method of claim 13, wherein the P/N-type mosaic comprises a checkerboard of P-type elements and N-type elements.

22. The method of claim 21, further comprising trimming the P/N-type mosaic so that it contains a desired number of P-type elements and N-type elements.

23. The method of claim 21, further comprising:
applying a diffusion barrier metallization to at least a subset of the P-type elements and N-type elements;
applying a first patterned current-carrying metallization to a first side of the P/N-type mosaic to form a thermoelectric circuit;
applying a second diffusion barrier metallization to at least a second subset of the P-type elements and N-type elements on a second side of the P/N-type mosaic;
applying a second patterned current-carrying metallization to the second side of the P/N-type mosaic to form a thermoelectric circuit.

24. The method of claim 23, further comprising:
applying a first ceramic plate to the first side of the P/N-type mosaic; and
applying a second ceramic plate to the second side of the P/N-type mosaic.

25. The method of claim 1, further comprising:
creating a plurality of channels in the composite P/N-type brick;
back-filling the plurality of channels in the composite P/N-type brick with an electrically and thermally insulating adhesive so that a P/N-type grid of P-type elements and N-type elements is formed.

26. The method of claim 25, wherein the electrically and thermally insulating adhesive is epoxy.

27. The method of claim 25, wherein:
streets of approximately uniform width are present between the P-type material wafers and the N-type material wafers in the composite P/N-type brick;
the respective widths of each channel are approximately equal to one another; and
the width of each channel corresponds to the width of one of the streets of approximately uniform width.

28. The method of claim 25, wherein the plurality of channels in the composite P/N-type brick extend transversely through the P-type material wafers and the N-type material wafers in the composite P/N-type brick.

29. The method of claim 25, wherein creating a plurality of channels in the composite P/N-type brick comprises sawing the channels in the composite P/N-type brick.

30. The method of claim 29, wherein:
streets of approximately uniform width are present between the P-type material wafers and the N-type material wafers in the composite P/N-type brick;
the respective widths of each channel are approximately equal to one another; and
the kerf of the cut left by sawing is approximately equal in width to the width of one of the streets of approximately uniform width.

31. The method of claim 25 further comprising trimming the P/N-type grid of P-type elements and N-type elements so that it contains a desired number of P-type elements and N-type elements.

32. The method of claim 31, further comprising:
applying a diffusion barrier metallization to at least a subset of the P-type elements and N-type elements;
applying a first patterned current-carrying metallization to a first side of the P/N-type grid of P-type elements and N-type elements to form a thermoelectric circuit;
applying a second diffusion barrier metallization to at least a second subset of the P-type elements and N-type elements on a second side of the P/N-type grid of P-type elements and N-type elements;
applying a second patterned current-carrying metallization to the second side of the P/N-type grid of P-type elements and N-type elements to form a thermoelectric circuit.

33. The method of claim 32, further comprising:
applying a first ceramic plate to the first side of the P/N-type grid of P-type elements and N-type elements; and
applying a second ceramic plate to the second side of the P/N-type grid of P-type elements and N-type elements.
